(19) United States
(12) Patent Application Publication
(10) Pub. No.: US 2025/0375849 A1
(43) Pub. Date: Dec. 11, 2025

(54) Chip Product Polishing System and Method

(71) Applicants: Measurement Specialties (Chengdu) Ltd., Chengdu (CN); TE Connectivity Solutions GmbH, Schaffhausen (CH); Tyco Electronics (Shanghai) Co., Ltd., Shanghai (CN)

(72) Inventors: Rong Zhang, Shanghai (CN); Dandan (Emily) Zhang, Shanghai (CN); Roberto Francisco-Yi Lu, Middletown, PA (US); Lan Gong, Chengdu (CN); Lei (Alex) Zhou, Shanghai (CN); Ping Huang, Chengdu (CN); Huairong Liu, Chengdu (CN); Senmiao Hu, Shanghai (CN); Xianghao (Jorge) Bao, Shanghai (CN); Ao He, Shanghai (CN); Xiaoxiao Wang, Shanghai (CN); Zilong Cheng, Shanghai (CN); Yao Chen, Shanghai (CN)

(73) Assignees: Measurement Specialties (Chengdu) Ltd., Sichuan (CN); TE Connectivity Solutions GmbH, Schaffhausen (CH); Tyco Electronics (Shanghai) Co., Ltd., Shanghai (CN)

(21) Appl. No.: 19/229,058

(22) Filed: Jun. 5, 2025

(30) Foreign Application Priority Data
Jun. 5, 2024 (CN) 202410727529.7

(51) Int. Cl. B24B 49/10; B24B 41/00; H01L 21/306

(52) U.S. Cl. CPC B24B 49/10; B24B 41/005; H01L 21/30625

(57) ABSTRACT

A chip product polishing system includes a product carrier having a base and a fixture detachably assembled to the base for clamping and fixing a chip product, a rotary table rotating the product carrier and the chip product loaded on the product carrier from an initial resistance detection station to a chip polishing station, a polishing wheel at the chip polishing station that polishes a chip of the chip product, and a polishing robot at the chip polishing station. The polishing robot moves the chip of the chip product clamped by the fixture onto the polishing wheel for polishing by grasping and moving the fixture. The polishing robot has an artificial intelligence control device that controls a polishing amount of the chip, so that a difference between a resistance value of the chip and a predetermined resistance value is within a predetermined range.

### CROSS-REFERENCE TO RELATED APPLICATION

This application claims the benefit of the filing date under 35 U.S.C. § 119(a)-(d) of Chinese Patent Application No. 202410727529.7, filed on Jun. 5, 2024.

### FIELD OF THE INVENTION

The present invention relates to a chip product polishing system and a method for polishing chip products using the chip product polishing system.

### BACKGROUND OF THE INVENTION

A chip product typically includes a chip and a lead connected to the chip. In some applications, it is desirable for the chip to have a predetermined resistance value. However, the initial resistance values of chip products vary greatly. Therefore, it is necessary to adjust the resistance value of the chip by manual polishing, so that the difference between the resistance value of the chip and the predetermined resistance value is within the predetermined range. However, due to the fact that chip products are usually very small, manual polishing can easily damage the chips, and manual polishing is very time-consuming and difficult to precisely control the polishing amount, relying entirely on the experience of workers.

### SUMMARY OF THE INVENTION

A chip product polishing system includes a product carrier having a base and a fixture detachably assembled to the base for clamping and fixing a chip product, a rotary table rotating the product carrier and the chip product loaded on the product carrier from an initial resistance detection station to a chip polishing station, a polishing wheel at the chip polishing station that polishes a chip of the chip product, and a polishing robot at the chip polishing station. The polishing robot moves the chip of the chip product clamped by the fixture onto the polishing wheel for polishing by grasping and moving the fixture. The polishing robot has an artificial intelligence control device that controls a polishing amount of the chip, so that a difference between a resistance value of the chip and a predetermined resistance value is within a predetermined range.

### BRIEF DESCRIPTION OF THE DRAWINGS

Features of the present invention will become more apparent by describing in detail exemplary embodiments thereof with reference to the accompanying drawings, in which:

FIG. 1 shows an illustrative view of a chip product polishing system according to an exemplary embodiment of the present invention;

FIG. 2 shows an illustrative assembly view of a product carrier for loading chip products according to an exemplary embodiment of the present invention; and

FIG. 3 shows an illustrative exploded view of a product carrier for loading chip products according to an exemplary embodiment of the present invention.

### DETAILED DESCRIPTION

Exemplary embodiments of the present disclosure will be described hereinafter in detail with reference to the attached drawings, wherein like reference numerals refer to like elements. The present disclosure may, however, be embodied in many different forms and should not be construed as being limited to the embodiments set forth herein; rather, these embodiments are provided so that the present disclosure will convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

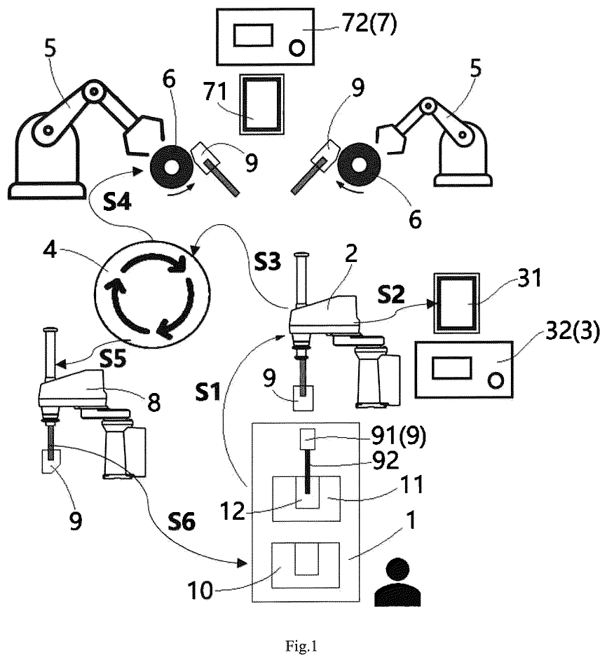

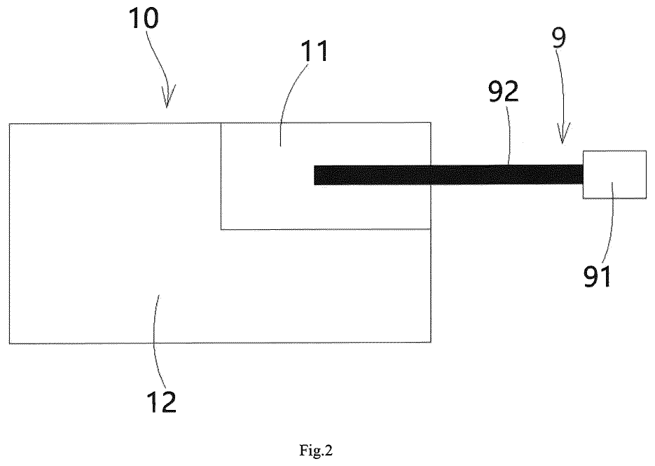

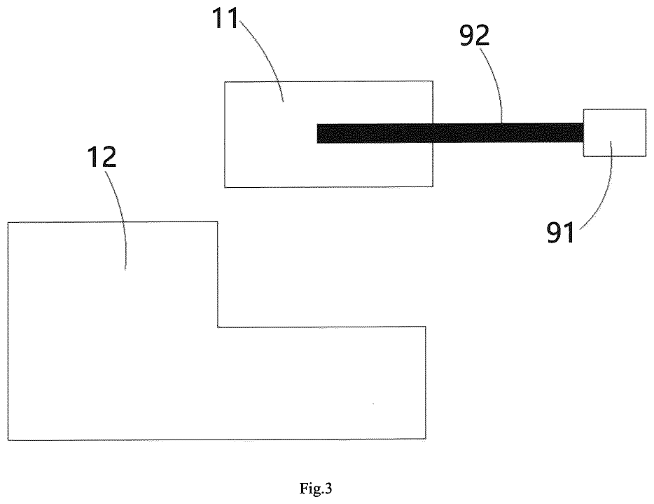

FIG. 1 shows an illustrative view of a chip product polishing system according to an exemplary embodiment of the present invention. FIG. 2 shows an illustrative assembly view of a product carrier 10 for loading chip products according to an exemplary embodiment of the present invention. FIG. 3 shows an illustrative exploded view of the product carrier 10 for loading chip products 9 according to an exemplary embodiment of the present invention.

As shown in FIG. 1, in an exemplary embodiment of the present invention, a chip product polishing system is disclosed. The chip product polishing system includes: a product carrier 10, a rotary table 4, a polishing wheel 6, and a polishing robot 5. The product carrier 10 includes a base 12 and a fixture 11. The fixture 11 is detachably assembled to the base 12 for clamping and fixing the chip product 9, as shown in FIGS. 2 and 3. The rotary table 4 is used to rotate the product carrier 10 and the chip product 9 loaded on the product carrier 10 from the initial resistance detection station to the chip polishing station. The polishing wheel 6 is set at the chip polishing station to polish the chip 91 of the chip product 9. The polishing robot 5 is set at the chip polishing station. The polishing robot 5 moves the chip 91 of the chip product 9 clamped by the fixture 11 to the polishing wheel 6 for polishing by grasping and moving the fixture 11. The polishing robot 5 has an artificial intelligence control device for controlling the polishing amount of the chip 91, so that the difference between the resistance value of the polished chip 91 and the predetermined resistance value is within a predetermined range.

As shown in FIGS. 1 to 3, in the illustrated embodiment, the polishing robot 5 performs the polishing operation of the chip 91 by grasping and moving the fixture 11, rather than directly grasping and moving the chip 91 to perform the polishing operation of the chip 91, which can prevent damage to the chip 91.

As shown in FIGS. 2 and 3, in the illustrated embodiment, the fixture 11 is assembled onto the base 12 in a pluggable manner, allowing the polishing robot 5 to quickly remove the fixture 11 from the base 12 and quickly insert the fixture 11 into the base 12.

As shown in FIG. 1, in the illustrated embodiment, the chip product polishing system further includes a first resistance detection device 3 and a first operating robot 2. The first resistance detection device 3 is set at the initial resistance detection station, used to detect the initial resistance value of the chip 91 of the chip product 9 before being polished. The first operating robot 2 is set at the initial resistance detection station for grasping and moving the product carrier 10. The first operating robot 2 moves the grasped product carrier 10 and places the chip 91 of the chip product 9 loaded on the product carrier 10 into the first resistance detection device 3 to detect the initial resistance value of the chip 91 through the first resistance detection device 3.

In the illustrated embodiment, the artificial intelligence control device of the polishing robot 5 is connected in communication with the first resistance detection device 3 to obtain the initial resistance value of the chip 91. The artificial intelligence control device is suitable for calculating the polishing amount of the chip 91 based on the obtained initial resistance value.

As shown in FIG. 1, in the illustrated embodiment, the first resistance detection device 3 includes a first temperature control box 31 and a first detector 32. The first temperature control box 31 is used to accommodate the detected chip 91, so that the temperature of the detected chip 91 is equal to the predetermined temperature. The first detector 32 is used to detect the initial resistance value of chip 91 at the predetermined temperature. The first operating robot 2 places the chip 91 of the chip product 9 into the first temperature control box 31 by grasping and moving the product carrier 10. The artificial intelligence control device of the polishing robot 5 is connected in communication with the first detector 32 to obtain the initial resistance value detected by the first detector 32. In an embodiment, the first temperature control box 31 is an oil tank filled with temperature control oil.

As shown in FIG. 1, in the illustrated embodiment, the rotary table 4 has an installation part suitable for detachable fitting with the base 12 of the product carrier 10, so that the base 12 of the product carrier 10 can be assembled onto the installation part of the rotary table 4 in a detachable manner. After completing the initial resistance value detection of chip 91, the first operating robot 2 installs the product carrier 10 loaded with chip product 9 onto the installation part of the rotary table 4.

As shown in FIG. 1, in the illustrated embodiment, the chip product polishing system further includes a second resistance detection device 7, which is set at the chip polishing station to detect the resistance value of the chip 91 of the chip product 9 after polishing. After the polishing robot 5 completes the polishing of the chip 91, the polishing robot 5 places the chip 91 of the chip product 9 clamped on the fixture 11 into the second resistance detection device 7 by moving the fixture 11 to detect the resistance value of the polished chip 91.

In the illustrated embodiment, the artificial intelligence control device of the polishing robot 5 is connected in communication with the second resistance detection device 7 to obtain the polished resistance value of the chip 91 detected by the second resistance detection device 7. When the difference between the resistance value detected by the second resistance detection device 7 and the predetermined resistance value is within the predetermined range, the polishing robot 5 stops polishing the chip 91 and reinstalls the fixture 11 holding the chip 91 onto the base 12 of the rotary table 4.

When the difference between the resistance value detected by the second resistance detection device 7 and the predetermined resistance value exceeds the predetermined range, the artificial intelligence control device recalculates the polishing amount of the chip 91 based on the resistance value detected by the second resistance detection device 7 and controls the polishing robot 5 to continue polishing the chip 91 until the difference between the resistance value detected by the second resistance detection device 7 and the predetermined resistance value is within the predetermined range.

As shown in FIG. 1, in the illustrated embodiment, the second resistance detection device 7 includes a second temperature control box 71 and a second detector 72. The second temperature control box 71 is used to accommodate the detected chip 91, so that the temperature of the detected chip 91 is equal to the predetermined temperature. The second detector 72 is used to detect the resistance value of chip 91 at the predetermined temperature. The polishing robot 5 places the chip 91 of the chip product 9 into the second temperature control box 71 by grasping and moving the fixture 11. The artificial intelligence control device of the polishing robot 5 is connected in communication with the second detector 72 to obtain the resistance value detected by the second detector 72. In an embodiment, the second temperature control box 71 is an oil tank filled with temperature control oil.

As shown in FIG. 1, in the illustrated embodiment, the chip product polishing system includes two polishing wheels 6 and two polishing robots 5, which correspond to the two polishing wheels 6 respectively. Two polishing robots 5 respectively grasp and move two fixtures 11 to respectively place the chips 91 of two chip products 9 held by the two fixtures 11 onto two polishing wheels 6, so as to polish the chips 91 of two chip products 9 simultaneously.

In the illustrated embodiment, the chip product polishing system includes a single second resistance detection device 7, which is set between two polishing robots 5. The two polishing robots 5 share the single second resistance detection device 7 in an alternating manner.

In the illustrated embodiment, the rotary table 4 is also used to rotate the product carrier 10 and the polished chip products 9 loaded on the product carrier 10 from the chip polishing station to the product unloading station. The chip product polishing system also includes a second operating robot 8, which is set at the product unloading station and is suitable for grasping and moving the chip product 9 to unload the polished chip product 9 from the product carrier 10 and place it in a predetermined position.

As shown in FIG. 1, in the illustrated embodiment, the chip product polishing system further includes a conveying device 1, which is used to transport the product carrier 10 and the chip product 9 loaded on the product carrier 10 from the product loading station to the initial resistance detection station. The chip product 9 is manually or automatically loaded onto the empty product carrier 10 located on the conveying device 1 at the product loading station.

In the illustrated embodiment, the second operating robot 8 is also adapted to grasp and move the product carrier 10 to unload the empty product carrier 10 from the rotary table 4 and place it on the conveying device 1.

In the illustrated embodiment, as shown in FIGS. 1 to 3, the chip product 9 includes a lead 92 connected to the chip 91, and the fixture 11 fixes the chip product 9 by clamping the lead 92.

As shown in FIGS. 1 to 3, in another exemplary embodiment of the present invention, a chip product polishing method is also disclosed. The chip product polishing method includes the following steps:

S0: providing the above chip product polishing system;

S1: loading the chip product 9 onto an empty product carrier 10 located on the conveying device 1 and transport the product carrier 10 and the chip product 9 to the initial resistance detection station through the conveying device 1;

S2: using the first operating robot 2 to grab the product carrier 10 loaded with the chip product 9 from the conveying device 1, and placing the chip 91 of the product chip 91 into the first resistance detection device 3 by moving the grabbed product carrier 10 to detect the initial resistance value of the chip 91;

S3: using the first operating robot 2 to install the product carrier 10 loaded with the chip product 9 onto the rotary table 4, and rotating the product carrier 10 loaded with the chip product 9 from the initial resistance detection station to the product polishing station through the rotary table 4;

S4: using the polishing robot 5 to grab the fixture 11 of the product carrier 10 from the rotary table 4 and place the chip 91 of the chip product 9 clamped by the fixture 11 onto the polishing wheel 6 for polishing by moving the fixture 11; using the polishing robot 5 reinstalling the fixture 11 holding the chip 91 onto the base 12 of the rotary table 4 after completing the polishing of the chip 91; and rotating the fixture 11 holding the chip 91 from the product polishing station to the product unloading station through the rotary table 4;

S5: using the second operating robot 8 to remove the polished chip product 9 from the product carrier 10 and place the polished product chip 91 in the predetermined position; and

S6: using the second operating robot 8 to remove the empty product carrier 10 from the rotary table 4 and place the empty product carrier 10 onto the conveying device 1.

As shown in FIGS. 1 to 3, in the illustrated embodiment, the aforementioned step S4 includes:

S41: using the polishing robot 5 to remove the fixture 11 holding the product chip 91 from the base 12 of the product carrier 10;

S42: the polishing robot 5 uses an artificial intelligence control device to calculate and control the polishing amount of the chip 91 based on the initial resistance value of the chip 91;

S43: the polishing robot 5 places the polished chip 91 into the second resistance detection device 7 to detect the resistance value of the polished chip 91;

S44: the artificial intelligence control device judges whether the difference between the resistance value detected by the second resistance detection device 7 and the predetermined resistance value is within the predetermined range; if the judgment result is no, the following step S45 is executed; otherwise, the following step S46 is executed;

S45: the artificial intelligence control device recalculates the polishing amount of the chip 91 based on the resistance value detected by the second resistance detection device 7 and controls the polishing robot 5 to continue polishing the chip 91 until the difference between the resistance value of the chip 91 and the predetermined resistance value is within the predetermined range; and

S46: using the polishing robot 5 to reinstall the fixture 11 holding the chip 91 onto the base 12 of the rotary table 4; and rotating the product carrier 10 and the polished chip product 9 loaded on it from the product polishing station to the product unloading station through the rotary table 4.

In the aforementioned step S1, the chip product 9 is loaded onto the empty product carrier 10 located on the conveying device 1 manually or using an automatic loading device (such as a robot) set at the product loading station.

In the aforementioned exemplary embodiments, the chip product polishing system can automatically achieve precise polishing of the chip, improve the polishing efficiency of the chip, and not damage the chip.

It should be appreciated for those skilled in this art that the above embodiments are intended to be illustrative, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

As used herein, an element recited in the singular and preceded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

1. A chip product polishing system, comprising:
a product carrier including a base and a fixture detachably assembled to the base for clamping and fixing a chip product;
a rotary table rotating the product carrier and the chip product loaded on the product carrier from an initial resistance detection station to a chip polishing station;
a polishing wheel at the chip polishing station that polishes a chip of the chip product; and
a polishing robot at the chip polishing station, which moves the chip of the chip product clamped by the fixture onto the polishing wheel for polishing by grasping and moving the fixture, the polishing robot has an artificial intelligence control device that controls a polishing amount of the chip, so that a difference between a resistance value of the chip and a predetermined resistance value is within a predetermined range.

2. The chip product polishing system of claim 1, wherein the fixture is assembled onto the base in a pluggable manner, the polishing robot is capable of removing the fixture from the base and inserting the fixture into the base.

3. The chip product polishing system of claim 1, further comprising:
a first resistance detection device at the initial resistance detection station that detects an initial resistance value of the chip of the chip product before being polished; and
a first operating robot at the initial resistance detection station that grasps and moves the product carrier, the first operating robot moves the product carrier and places the chip of the chip product loaded on the product carrier into the first resistance detection device to detect the initial resistance value of the chip through the first resistance detection device.

4. The chip product polishing system of claim 3, wherein the artificial intelligence control device of the polishing robot is connected in communication with the first resistance detection device to obtain the initial resistance value of the chip, the artificial intelligence control device calculates the polishing amount of the chip based on the initial resistance value.

5. The chip product polishing system of claim 3, wherein the first resistance detection device includes:
a first temperature control box accommodating the chip, so that a temperature of the chip is equal to a predetermined temperature; and
a first detector detecting the initial resistance value of the chip at the predetermined temperature, the first operating robot places the chip of the chip product into the first temperature control box by grasping and moving the product carrier, the artificial intelligence control device of the polishing robot is connected in communication with the first detector to obtain the initial resistance value detected by the first detector.

6. The chip product polishing system of claim 5, wherein the first temperature control box is an oil tank filled with a temperature control oil.

7. The chip product polishing system of claim 3, wherein the rotary table has an installation part detachably fitting with the base of the product carrier, the base of the product carrier is capable of being assembled onto the installation part of the rotary table in a detachable manner, and after completing detection of the initial resistance value of the chip, the first operating robot installs the product carrier loaded with the chip product onto the installation part of the rotary table.

8. The chip product polishing system of claim 3, further comprising a second resistance detection device at the chip polishing station that detects the resistance value of the chip of the chip product after being polished, and after the polishing robot completes polishing of the chip, the polishing robot places the chip of the chip product clamped on the fixture into the second resistance detection device by moving the fixture to detect the resistance value of the chip.

9. The chip product polishing system of claim 8, wherein the artificial intelligence control device of the polishing robot is connected in communication with the second resistance detection device to obtain the resistance value of the chip detected by the second resistance detection device, and when the difference between the resistance value detected by the second resistance detection device and the predetermined resistance value is within the predetermined range, the polishing robot stops polishing the chip and reinstalls the fixture holding the chip onto the base.

10. The chip product polishing system of claim 9, wherein, when the difference between the resistance value detected by the second resistance detection device and the predetermined resistance value exceeds the predetermined range, the artificial intelligence control device recalculates the polishing amount of the chip based on the resistance value detected by the second resistance detection device and controls the polishing robot to continue polishing the chip until the difference between the resistance value detected by the second resistance detection device and the predetermined resistance value is within the predetermined range.

11. The chip product polishing system of claim 8, wherein the second resistance detection device includes:
a second temperature control box accommodating the detected chip, so that a temperature of the chip is equal to a predetermined temperature; and
a second detector detecting the resistance value of the chip, the polishing robot places the chip of the chip product into the second temperature control box by grasping and moving the fixture, the artificial intelligence control device of the polishing robot is connected in communication with the second detector to obtain the resistance value detected by the second detector.

12. The chip product polishing system of claim 11, wherein the second temperature control box is an oil tank filled with a temperature control oil.

13. The chip product polishing system of claim 8, wherein the polishing wheel is one of a pair of polishing wheels, the polishing robot is one of a pair of polishing robots, and the fixture is one a pair of fixtures, the polishing robots respectively grasp and move the fixtures to respectively place the chips of a pair of chip products held by the fixtures onto the polishing wheels, to simultaneously polish the chips of the chip products.

14. The chip product polishing system of claim 13, wherein the second resistance detection device is a single second resistance detection device positioned between the polishing robots, the polishing robots share the single second resistance detection device in an alternating manner.

15. The chip product polishing system of claim 8, wherein the rotary table rotates the product carrier and the chip product loaded on the product carrier from the chip polishing station to a product unloading station, the chip product polishing system further comprises a second operating robot at the product unloading station that grasps and moves the chip product to unload the chip product from the product carrier and place it in a predetermined position.

16. The chip product polishing system of claim 15, further comprising a conveying device transporting the product carrier and the chip product loaded on the product carrier from a product loading station to the initial resistance detection station, the chip product is loaded onto an empty product carrier located on the conveying device manually or through an automatic loading device at the product loading station.

17. The chip product polishing system of claim 16, wherein the second operating robot grasps and moves the product carrier to unload the empty product carrier from the rotary table and place it on the conveying device.

18. The chip product polishing system of claim 1, wherein the chip product has a lead connected to the chip, the fixture fixes the chip product by clamping the lead.

19. A method for polishing chip products, comprising:
providing a chip product polishing system including:
a product carrier including a base and a fixture detachably assembled to the base for clamping and fixing a chip product;
a rotary table;
a polishing wheel; and
a polishing robot having an artificial intelligence control device that controls a polishing amount of the chip, so that a difference between a resistance value of the chip and a predetermined resistance value is within a predetermined range;
loading the chip product onto the product carrier located on a conveying device and transporting the product carrier and the chip product to the initial resistance detection station through the conveying device;
using a first operating robot to grab the product carrier loaded with the chip product from the conveying device, and placing the chip of the product chip into a first resistance detection device by moving the product carrier to detect an initial resistance value of the chip;
using the first operating robot to install the product carrier loaded with the chip product onto the rotary table, and rotating the product carrier loaded with the chip product from the initial resistance detection station to a product polishing station through the rotary table;
using the polishing robot to grab the fixture of the product carrier from the rotary table and place the chip of the chip product clamped by the fixture onto the polishing wheel for polishing by moving the fixture;
using the polishing robot to reinstall the fixture holding the chip onto the base of the rotary table after completing the polishing of the chip;
rotating the fixture holding the chip from the product polishing station to a product unloading station through the rotary table;
using a second operating robot to remove the chip product from the product carrier and place the product chip in a predetermined position; and
using the second operating robot to remove the product carrier from the rotary table and place the product carrier onto the conveying device.

20. The method of claim 19, further comprising:
using the polishing robot to remove the fixture holding the product chip from the base of the product carrier;
using the artificial intelligence control device to calculate and control the polishing amount of the chip based on the initial resistance value of the chip;
placing the polished chip into a second resistance detection device to detect the resistance value of the chip;
judging with the artificial intelligence control device whether the difference between the resistance value detected by the second resistance detection device and the predetermined resistance value is within the predetermined range;
if the judgment result is no, the artificial intelligence control device recalculates the polishing amount of the chip based on the resistance value detected by the second resistance detection device and controls the polishing robot to continue polishing the chip until the difference between the resistance value of the chip and the predetermined resistance value is within the predetermined range; and
if the judgment result is yes, using the polishing robot to reinstall the fixture holding the chip onto the base of the rotary table; and rotating the product carrier and the chip product loaded on it from the product polishing station to the product unloading station through the rotary table.
